(19) United States
(12) Patent Application Publication
(10) Pub. No.: US 2013/0050960 A1
(43) Pub. Date: Feb. 28, 2013

(54) PORTABLE ELECTRONIC DEVICE

(71) Applicants: Yu-Chia CHANG, Taipei (TW); Wang-Ta HSIEH, Taipei (TW)

(72) Inventors: Yu-Chia CHANG, Taipei (TW); Wang-Ta HSIEH, Taipei (TW)

(21) Appl. No.: 13/587,311

(22) Filed: Aug. 16, 2012

Related U.S. Application Data
(60) Provisional application No. 61/526,046, filed on Aug. 22, 2011.

(51) Int. Cl. H05K 7/02

(52) U.S. Cl. 361/748

(57) ABSTRACT

A portable electronic device includes an integration unit and a main circuit. The integration unit includes a carrier and at least one electronic element disposed on the carrier. The electronic element includes an antenna unit, a button input unit or a sound transmission unit. The main circuit is electrically connected to the electronic element through a conducting wire.

### CROSS REFERENCE TO RELATED APPLICATIONS

The non-provisional patent application claims priority to U.S. provisional patent application with Ser. No. 61/526,046 filed on Aug. 22, 2011. This and all other extrinsic materials discussed herein are incorporated by reference in their entirety.

### BACKGROUND OF THE INVENTION

1. Field of Invention

The present disclosure relates to a portable electronic device and, in particular, to a portable electronic device with integrated antenna unit and button input unit.

2. Related Art

The conventional feed point of antenna is usually connected to the circuit board by some mechanisms such as the elastic sheet or pin. Thus, the circuit board must be extended to the place of the antenna, so that the elastic sheet or pin can be connected to the circuit board by surface mounting technology (SMT). However, this configuration increases not only the length of the circuit board but also the thickness of the portable electronic device.

### SUMMARY OF THE INVENTION

A portable electronic device of this disclosure includes an integration unit and a main circuit. The integration unit includes a carrier and at least one electronic element disposed on the carrier. The electronic element includes an antenna unit, a button input unit or a sound transmission unit. The main circuit is electrically connected to the electronic element through a conducting wire.

In one embodiment, the electronic element comprises an antenna unit electrically connected to the main circuit through the conductive wire, and the conductive wire comprises a coaxial cable or a flat cable.

In one embodiment, the electronic element comprises a button input unit electrically connected to the main circuit through the conductive wire, and the conductive wire comprises a coaxial cable or a flat cable.

In one embodiment, the electronic element comprises a sound transmission unit electrically connected to the main circuit through the conductive wire, and the conductive wire comprises a coaxial cable or a flat cable.

In one embodiment, the portable electronic device further comprises a touch control unit electrically connected to the main circuit through the conductive wire.

In one embodiment, the antenna unit has an exposed portion.

In one embodiment, the portable electronic device further comprises a battery having a grounding portion, and the grounding portion is coupled with the exposed portion.

In one embodiment, the grounding portion is coupled with the exposed portion through a conductive member.

As mentioned above, the portable electronic device of this disclosure includes a carrier for integrating at least one electronic element (e.g. an antenna unit and a button input unit) into a single component. In this case, the antenna unit and the button input unit can be integrated, so that the internal space of the portable electronic device can be utilized more efficiently, thereby further decreasing the thickness of the portable electronic device. In addition, the disclosure may further integrate the microphone, antenna unit, and button input unit so as to increase the integration efficiency of the portable electronic device.

These and other features, aspects and advantages of the present invention will become better understood with regard to the following description, appended claims, and accompanying drawings.

### BRIEF DESCRIPTION OF THE DRAWINGS

FIG. 1A is a schematic diagram showing the rear side of a portable electronic device according to a first embodiment of the disclosure;

FIG. 1B is a schematic diagram showing the front side of the portable electronic device according to the first embodiment of the disclosure;

FIG. 2 is a schematic diagram of a carrier;

FIG. 3 is a schematic diagram showing the rear side of a portable electronic device according to a second embodiment of the disclosure;

FIG. 4A is a schematic diagram showing the rear side of a portable electronic device according to a third embodiment of the disclosure;

FIG. 4B is a schematic diagram showing the front side of the portable electronic device according to the third embodiment of the disclosure; and

FIG. 5 is a schematic diagram showing the rear side of a portable electronic device according to a fourth embodiment of the disclosure.

### DETAILED DESCRIPTION OF THE INVENTION

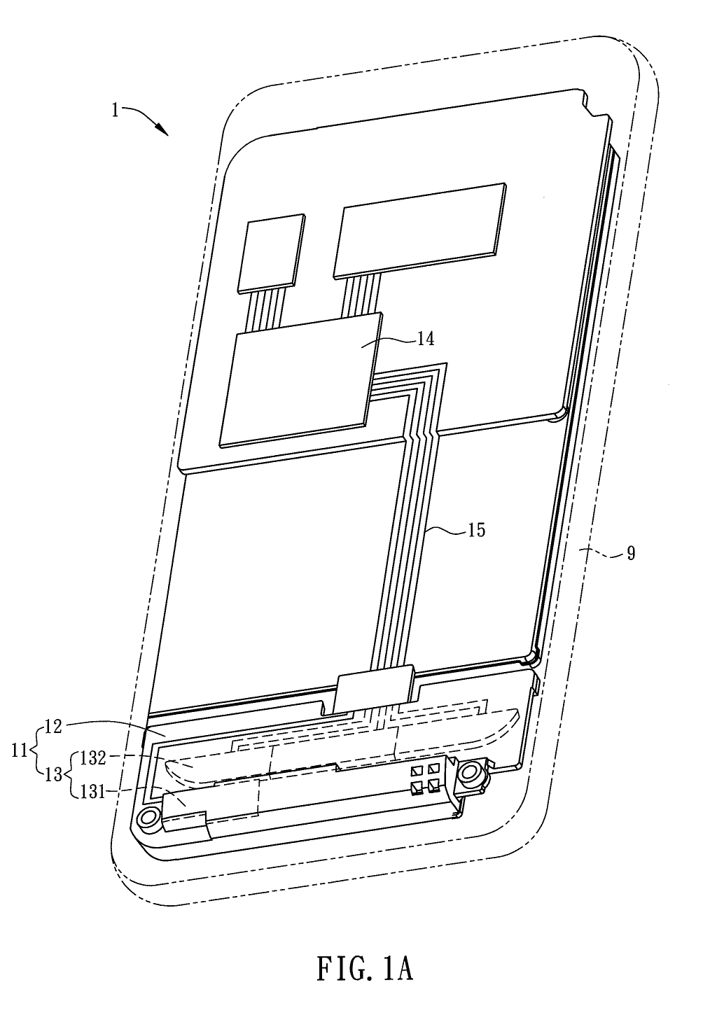

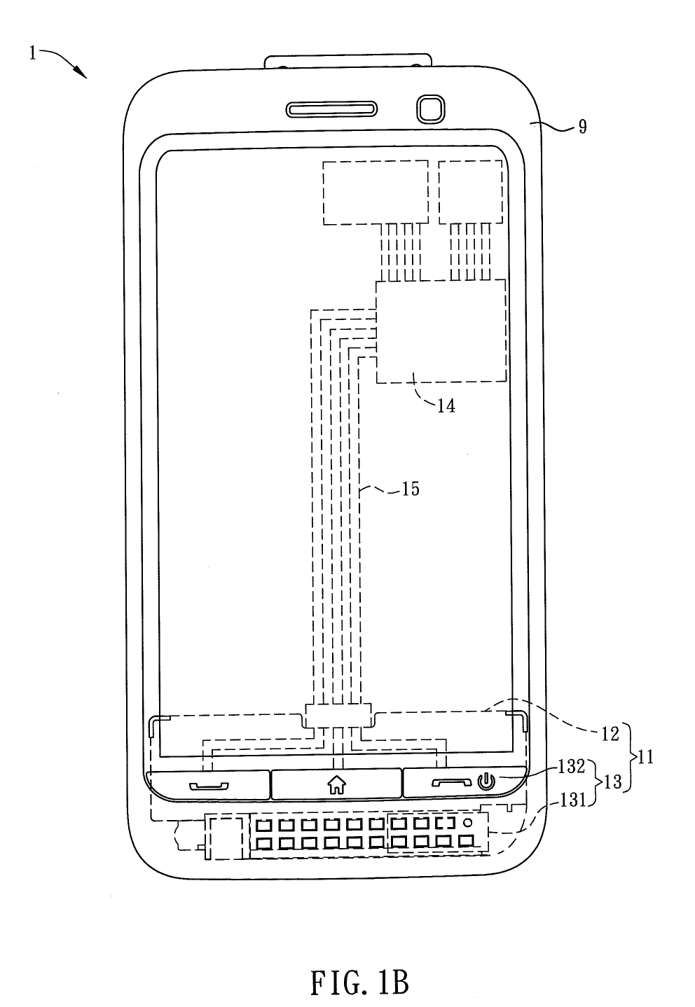

FIG. 1A is a schematic diagram showing the rear side of a portable electronic device 1 according to a first embodiment of the disclosure, and FIG. 1B is a schematic diagram showing the front side of the portable electronic device 1. Referring to FIGS. 1A and 1B, the portable electronic device 1 includes an integration unit 11 and a main circuit 14.

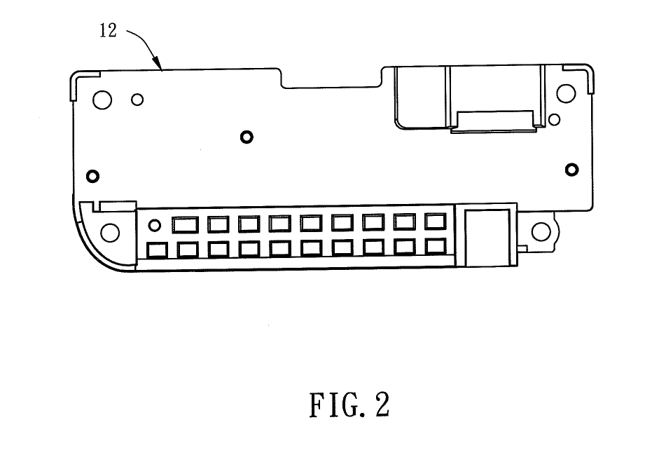

The integration unit 11 includes a carrier 12 and at least one electronic element 13. FIG. 2 is a schematic diagram of a carrier 12. As shown in FIG. 2, the carrier 12 is a plate body made of plastic for example. Of course, in practice, the material of the carrier 12 is not limited herein and may include other insulation materials in any other shape.

The electronic element 13 is disposed on the carrier 12. In this embodiment, the electronic element 13 contains an antenna unit 131. For example, the antenna unit 131 is a flexible printed circuit board and is disposed on the carrier 12 by adhering. In this embodiment, the antenna unit 131 is attached to one side of the carrier 12 by insulation tape.

In this embodiment, the electronic element 13 includes a button input unit 132, which is disposed on the other side of the carrier 12. For example, the button input unit 132 is a physical button such as a menu button with the function of “return to main menu” or a back button with the function of “go to previous page”. Of course, in practice, the button input unit 132 may includes a plurality of physical buttons such as the menu button and back button, which is not limited herein.

In this embodiment, the integration unit 11 is disposed at one end of a casing 9 of the portable electronic device 1, and it is disposed on the casing 9 by screwing, adhering or locking.

The main circuit 14 includes the major circuits of the portable electronic device 1, which include a processor, a memory and the likes. In this embodiment, the mail circuit 14 is disposed at the other end of the casing 9, and the main circuit 14 is electrically connected to the electronic element 13 through a conductive wire. In more specific, the conductive wire is a flat cable 15, and the antenna unit 131 is electrically connected to the main circuit 14 through the flat cable 15. Thus, the antenna signals can be transmitted between the antenna unit 131 and the main circuit 14. In addition, the button input unit 132 is also electrically connected to the main circuit 14 through the flat cable 15, so that the button signals can be transmitted to the main circuit 14 through the flat cable 15. In other words, the antenna unit 131 and the button input unit 132 can communicate with the main circuit 14 through the flat cable 15. Herein, the flat cable 15 can be composed of a plurality of printed conductive wires or any applicable conductive material such as copper lines or silver lines.

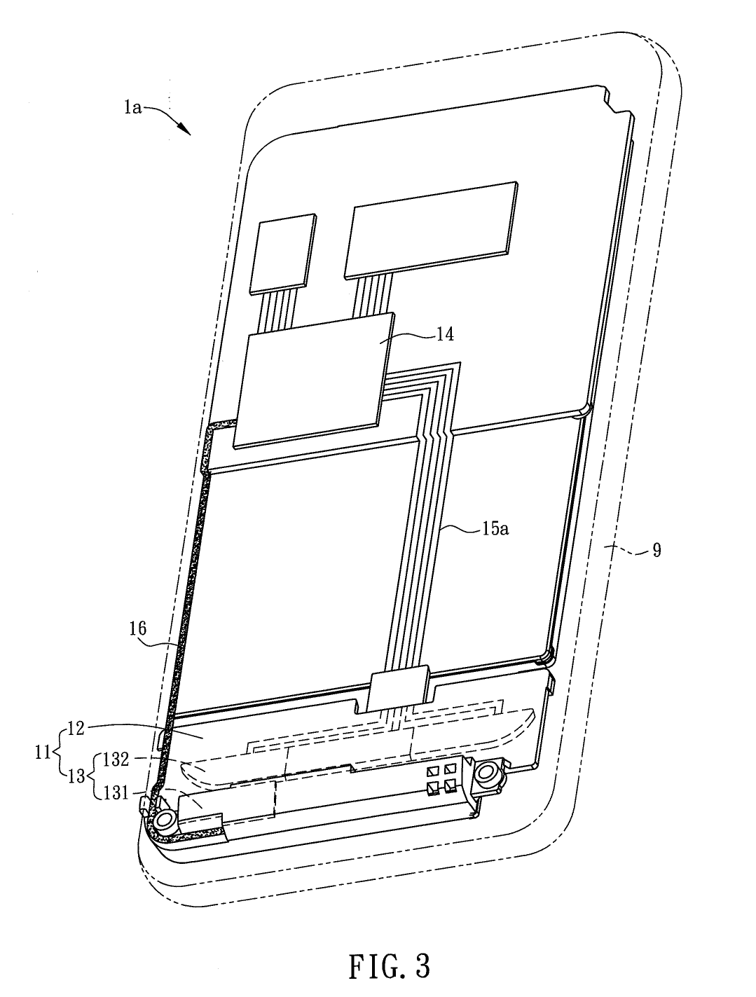

FIG. 3 is a schematic diagram showing the rear side of a portable electronic device 1a according to a second embodiment of the disclosure. The portable electronic device 1a is mostly the same as the above-mentioned portable electronic device 1, and their differences will be described hereinbelow while the similar parts are omitted.

In one embodiment, the conductive wire includes a flat cable 15a and a coaxial cable 16. The antenna unit 131 is electrically connected to the main circuit 14 through the coaxial cable 16 instead of the flat cable 15a, so that the antenna signals can be transmitted between the antenna unit 131 and the main circuit 14. Preferably, the coaxial cable 16 is positioned along the edge of the casing 9 so as to prevent the signal interference of other electronic components. The coaxial cable 16 is connected to the antenna unit 131 and the main circuit 14 by soldering. Besides, the button input unit 132 is still electrically connected to the main circuit through the flat cable 15a.

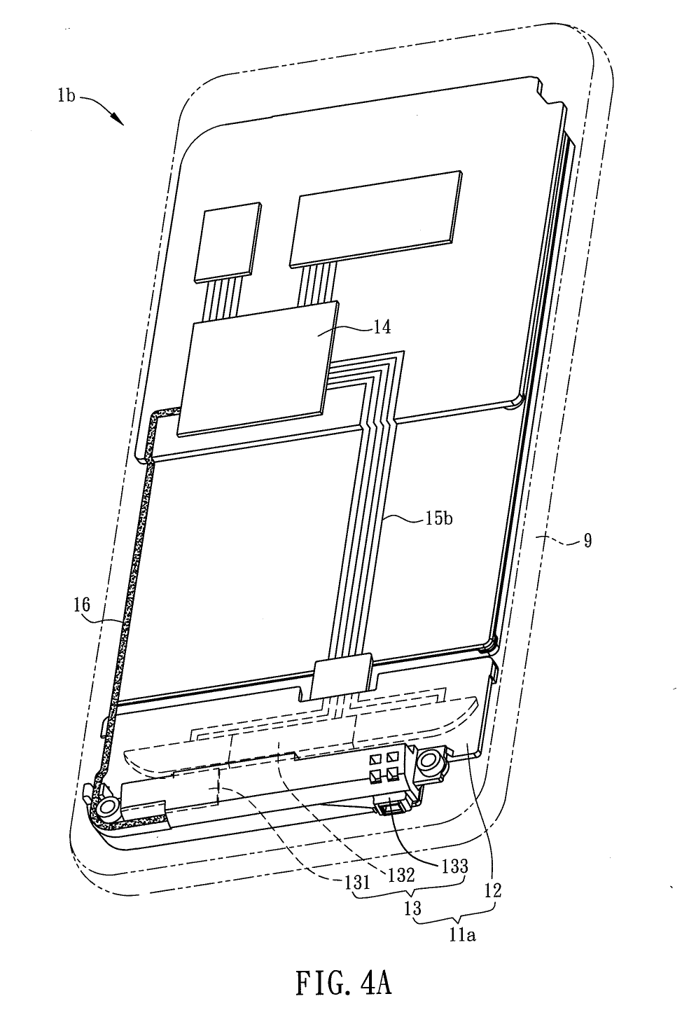

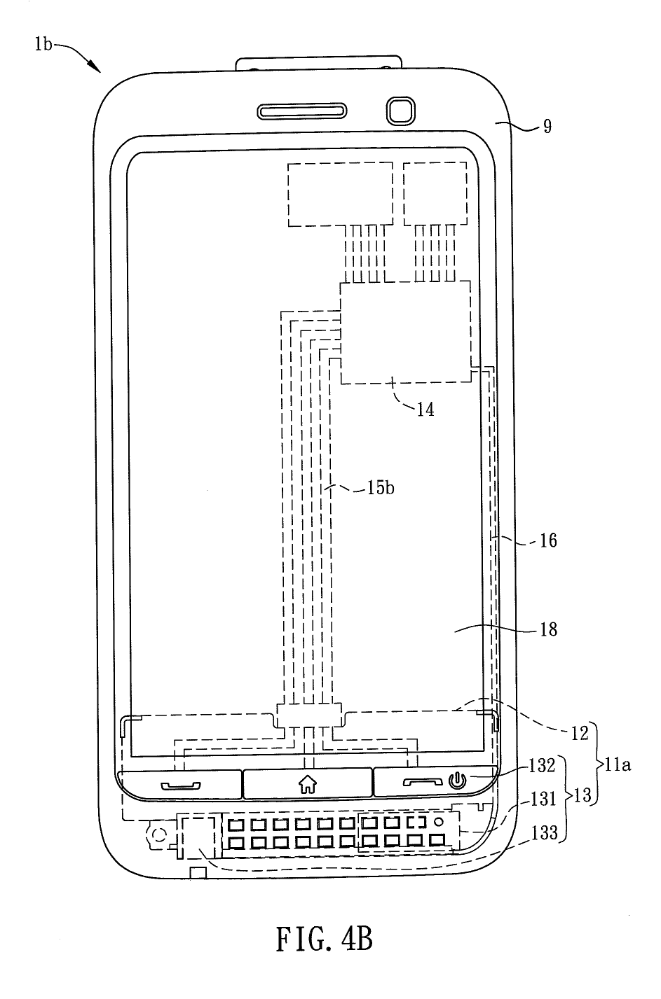

FIG. 4A is a schematic diagram showing the rear side of a portable electronic device 1b according to a third embodiment of the disclosure, and FIG. 4B is a schematic diagram showing the front side of the portable electronic device 1b. Referring to FIGS. 4A and 4B, the portable electronic device 1b is mostly the same as the above-mentioned portable electronic device 1a, and their differences will be described hereinbelow while the similar parts are omitted.

In this embodiment, the integration unit 11a of the portable electronic device 1b further includes a sound transmission unit 133. For example, the sound transmission unit 133 is a microphone for receiving external sounds. Accordingly, the entire thickness of the portable electronic device 1b can be sufficiently decreased by integrating the antenna unit 131, the button input unit 132 and the sound transmission unit 133 in the carrier 12. Herein, the sound transmission unit 133 is electrically connected to the main circuit 14 through the flat cable 15b, so that the sound signals can be transmitted to the main circuit 14 through the flat cable 15b.

In addition, the portable electronic device 1b further includes a touch control unit 18 electrically connected to the main circuit 14 through the flat cable 15b, so that the touch control signals can be transmitted to the main circuit 14 through the flat cable 15b. In other words, the touch control signals from the touch control unit 18, the sound signals from the sound transmission unit 133 and the button signals from the button input unit 132 are all integrated and transmitted to the main circuit 14 through the flat cable 15b. Besides, the coaxial cable 16 is configured between the antenna unit 131 and the main circuit 14 for transmitting the antenna signals.

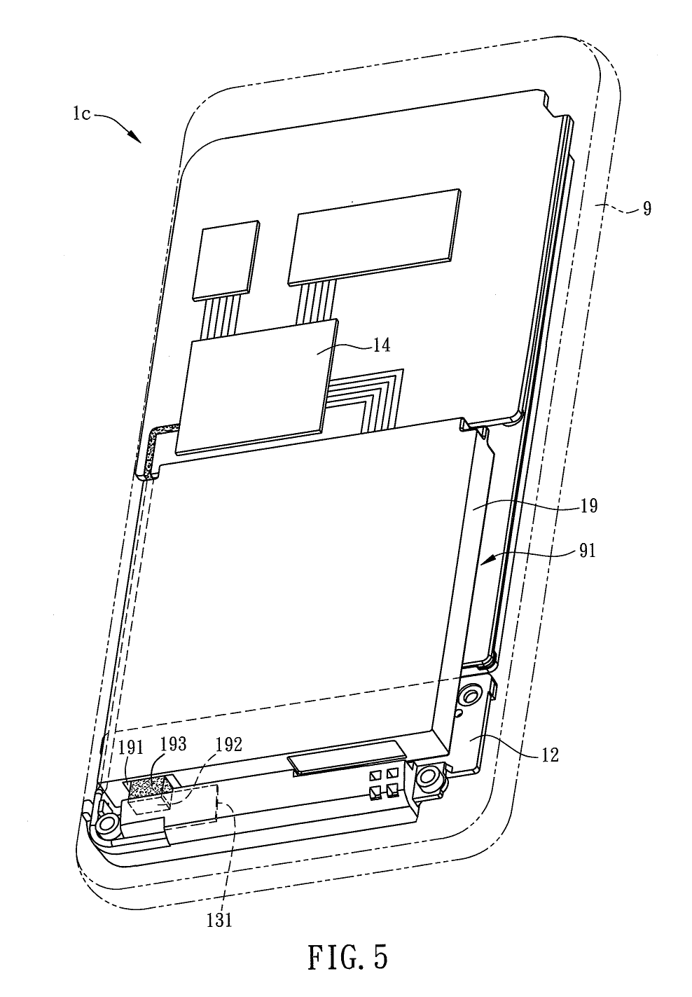

FIG. 5 is a schematic diagram showing the rear side of a portable electronic device 1c according to a fourth embodiment of the disclosure. Referring to FIG. 5, the portable electronic device 1c is mostly the same as the above-mentioned portable electronic device 1a, and their differences will be described hereinbelow while the similar parts are omitted.

In this embodiment, the portable electronic device 1c further includes a battery 19. Preferably, the battery 19 is disposed in an accommodating space 91 between the main circuit 14 and the integration unit 11. The battery 19 can be combined with a back cover (not shown) to carry out the integrated back cover design. Of course, the battery 19 may also be separated from the back cover and is detachably or non-detachably configured in the accommodating space 91. Herein, the battery 19 has a grounding portion 191, which is a portion of a metal member in the battery 19.

In addition, the antenna unit 131 further has an exposed portion 192, which is a conductive body and coupled with the grounding portion 191. The exposed portion 192 of the antenna unit 131 can be directly connected to the grounding portion 191 of the battery 9; otherwise, the exposed portion 192 of the antenna unit 131 can be connected to the grounding portion 191 of the battery 19 indirectly (through a conductive member 193). For example, the conductive member 193 is the conductive foam, conductive rubber or other conductive materials. Besides, the conductive member 193 can be attached to the exposed portion 192 of the antenna unit 131 or the grounding portion 191 of the battery 19 by conductive glue. No matter they are directly or indirectly coupled, the antenna unit 131 can be coupled to the metal member (ground terminal) of the battery 19 through the exposed portion 192 and the grounding portion 191 and then grounded.

Although the invention has been described with reference to specific embodiments, this description is not meant to be construed in a limiting sense. Various modifications of the disclosed embodiments, as well as alternative embodiments, will be apparent to persons skilled in the art. It is, therefore, contemplated that the appended claims will cover all modifications that fall within the true scope of the invention.

What is claimed is:

1. A portable electronic device, comprising:
an integration unit comprising a carrier and at least one electronic element disposed on the carrier; and
a main circuit electrically connected to the electronic element through a conducting wire.

2. The portable electronic device of claim 1, wherein the electronic element comprises an antenna unit electrically connected to the main circuit through the conductive wire, and the conductive wire comprises a coaxial cable or a flat cable.

3. The portable electronic device of claim 1, wherein the electronic element comprises a button input unit electrically connected to the main circuit through the conductive wire, and the conductive wire comprises a coaxial cable or a flat cable.

4. The portable electronic device of claim 1, wherein the electronic element comprises a sound transmission unit electrically connected to the main circuit through the conductive wire, and the conductive wire comprises a coaxial cable or a flat cable.

5. The portable electronic device of claim 1, further comprising a touch control unit electrically connected to the main circuit through the conductive wire.

6. The portable electronic device of claim 2, wherein the antenna unit has an exposed portion.

7. The portable electronic device of claim 6, further comprising a battery having a grounding portion, and the grounding portion is coupled with the exposed portion.

8. The portable electronic device of claim 7, wherein the grounding portion is coupled with the exposed portion through a conductive member.
